(19) United States
(12) Patent Application Publication
(10) Pub. No.: US 2025/0089266 A1
(43) Pub. Date: Mar. 13, 2025

(54) MAGNETIC MEMORY DEVICE USING SPIN PUMPING

(71) Applicant: Korea Advanced Institute of Science and Technology, Daejeon (KR)

(72) Inventors: Kyung-Jin Lee, Daejeon (KR); Seok-Jong Kim, Daejeon (KR)

(21) Appl. No.: 18/759,559

(22) Filed: Jun. 28, 2024

(30) Foreign Application Priority Data
Sep. 12, 2023 (KR) 10-2023-0121007

(51) Int. Cl. H10B 61/00; H10N 50/10; H10N 50/80; H10N 50/85

(52) U.S. Cl. CPC H10B 61/00; H10N 50/10; H10N 50/80; H10N 50/85

(57) ABSTRACT

A magnetic memory device includes a non-magnetic conductive layer, an antiferromagnetic layer, and a free magnetic layer. The non-magnetic conductive layer is configured to receive electric power to generate a first spin current and a second spin current by the spin Hall effect. The antiferromagnetic layer is in contact with one face of the non-magnetic conductive layer. The antiferromagnetic layer is configured to receive the first spin current to generate a third spin current by spin pumping. One face of the free magnetic layer is in contact with the other face of the non-magnetic conductive layer. The free magnetic layer is configured to receive the second spin current and the third spin current. A magnetization direction of the free magnetic layer is switched by the second spin current and the third spin current.

### CROSS-REFERENCE TO RELATED APPLICATION

The present application claims priority from Korean Patent Application No. 10-2023-0121007, filed on Sep. 12, 2023, in the Korean Intellectual Property Office, the disclosure of which is incorporated herein in its entirety by reference.

### BACKGROUND

### 1. Field

The present disclosure relates to a magnetic memory device, and specifically to a magnetic memory device using a spin current generated by spin pumping in an antiferromagnetic layer, thereby dramatically lowering switching current density in a free magnetic layer.

### 2. Description of Related Art

A magnetic memory device is a memory device using a magnetic tunnel junction (MTJ). A magnetic tunnel junction consists of a free magnetic layer, a fixed magnetic layer, and a tunnel insulator layer provided in between the free magnetic layer and the fixed magnetic layer. The resistance of a magnetic tunnel junction varies according to the direction of relative magnetization of the free magnetic layer and the fixed magnetic layer. The magnetic memory device can write or read data using the difference of resistance in such a magnetic tunnel junction.

A memory device using the above-described magnetic tunnel junction is usually distinguished into an STT-MRAM (Spin-Transfer Torque MRAM), an SOT-MRAM (Spin-Orbit Torque MRAM), a Perpendicular MTJ (pMTJ), or an STNO-MRAM (Spin Transfer Torque Oscillator MRAM).

Among these, the operating mechanism of the spin-orbit torque MRAM (SOT-MRAM) is as follows. When in-plane electricity flows through a wire, a spin current is generated by the spin Hall effect. This spin current spreads to an adjacent magnetic layer and changes the magnetization direction of the free magnetic layer to control the resistance of the magnetic tunnel junction.

The spin-orbit torque MRAM (SOT-MRAM) has an advantage of significantly faster reading and writing rate than the Spin-Transfer Torque MRAM (STT-MRAM). Nonetheless, it has a shortcoming that the switching current density (which is required for changing the magnetization direction of the free magnetic layer) is high. In order to improve such a shortcoming, there is a demand for development of a spin-orbit torque MRAM having a low switching current density.

### SUMMARY

Contrived to supplement the shortcoming of a spin-orbit torque MRAM described above, an object of the present disclosure is to provide a magnetic memory device using a spin current generated by spin pumping, thereby not only allowing field-free switching of a magnetization direction of a free magnetic layer without applying an external magnetic field but also significantly reducing a switching current density.

Another object of the present disclosure is to provide a magnetic memory device with a spin current generated by spin pumping capable of switching a magnetization direction of a free magnetic layer by selecting at least one of a relationship between a polarization direction of a spin current provided to an antiferromagnetic layer and a direction of an easy magnetization axis of the antiferromagnetic layer and a relationship between a polarization direction of the spin current provided to the antiferromagnetic layer and a direction of a hard magnetization axis of the antiferromagnetic layer.

A magnetic memory device according to an embodiment of the present disclosure may include a non-magnetic conductive layer, an antiferromagnetic layer, and a free magnetic layer. A non-magnetic conductive layer may be configured to receive electric power to generate a first spin current and a second spin current caused by the spin Hall effect.

An antiferromagnetic layer may be in contact with one face of the non-magnetic conductive layer. An antiferromagnetic layer may be configured to receive the first spin current to generate a third spin current by spin pumping.

One face of a free magnetic layer may be in contact with other face of the non-magnetic conductive layer. A free magnetic layer may be configured to receive the second spin current and the third spin current.

A magnetization direction of the free magnetic layer may be switched by the second spin current and the third spin current.

According to one embodiment of the present disclosure, a first unit vector is defined to be parallel to at least one of an easy magnetization axis of the antiferromagnetic layer and a hard magnetization axis of the antiferromagnetic layer. A second unit vector is defined to be configured with component vectors of the first unit vector that are perpendicular to at least one of a direction of the first spin current, a direction of the second spin current, and a direction of the third spin current. A third unit vector is defined to be parallel to a polarization direction of the first spin current. A dot product of the second unit vector and the third unit vector may be a first value. An absolute value of the first value may be greater than 0 and smaller than or equal to 1.

A magnetic memory device according to one embodiment of the present disclosure may further comprise an insulator layer and a fixed magnetic layer. A face of the insulator layer may be in contact with the other face of the free magnetic layer. A face of the fixed magnetic layer may be in contact with the other face of the insulator layer.

According to one embodiment of the present disclosure, each of a free magnetic layer and a fixed magnetic layer may comprise at least one of Fe, Co, Ni, B, Si, and Zr.

A magnetic memory device according to one embodiment of the present disclosure may further comprise a first electrode and a power supply unit. A first electrode may be electrically connected to the non-magnetic conductive layer. A power supply unit may be configured for providing electric power to the non-magnetic conductive layer via the first electrode.

In one embodiment of the present disclosure, the first electrode may comprise at least one of Cu, Ta, Pt, W, Ti, Bi, and Ir.

In one embodiment of the present disclosure, the antiferromagnetic layer may comprise at least one of Ru, Ir, Pt, Mn, Cr, FeMn, NiO, and Fe₂O₃ or an oxide thereof.

In one embodiment of the present disclosure, the non-magnetic conductive layer may comprise at least one of Cu, Ta, Pt, W, Ti, and Bi.

A magnetic memory device according to one embodiment of the present disclosure may comprise a spin pumping structure and a magnetic tunnel junction structure. A spin pumping structure may comprise an antiferromagnetic layer and a non-magnetic conductive layer. A magnetic tunnel junction structure may be disposed on the spin pumping structure. A magnetic tunnel junction may comprise a free magnetic layer, an insulator layer, and a fixed magnetic layer.

The non-magnetic conductive layer may be configured to receive electric power to generate a first spin current and a second spin current by spin Hall effect. The antiferromagnetic layer may be configured to receive the first spin current to generate a third spin current by spin pumping. The free magnetic layer may be configured to receive the second spin current and the third spin current. A magnetization direction of the free magnetic layer may be switched by the second spin current and the third spin current.

In one embodiment of the present disclosure, a first unit vector is defined to be parallel to at least one of an easy magnetization axis of the antiferromagnetic layer and a hard magnetization axis of the antiferromagnetic layer. A second unit vector is defined to be configured with component vectors of the first unit vector that are perpendicular to at least one of a direction of the first spin current, a direction of the second spin current, and a direction of the third spin current. A third unit vector is defined to be parallel to a polarization direction of the first spin current. A dot product of the second unit vector and the third unit vector may be a first value. An absolute value of the first value may be greater than 0 and smaller than or equal to 1.

A magnetic memory device according to one embodiment of the present disclosure may further comprise a first electrode and a power supply unit. A first electrode may be electrically connected to the non-magnetic conductive layer. A power supply unit may be configured for providing electric power to the non-magnetic conductive layer via the first electrode.

In one embodiment of the present disclosure, the first electrode may comprise at least one of Cu, Ta, Pt, W, Ti, Bi, and Ir.

In one embodiment of the present disclosure, each of the free magnetic layer and the fixed magnetic layer may comprise at least one of Fe, Co, Ni, B, Si, and Zr.

In one embodiment of the present disclosure, the antiferromagnetic layer may comprise at least one of Ru, Ir, Pt, Mn, Cr, FeMn, NiO, and Fe₂O₃ or an oxide thereof.

In one embodiment of the present disclosure, the non-magnetic conductive layer may comprise at least one of Cu, Ta, Pt, W, Ti, and Bi.

A magnetic memory device according to one embodiment of the present disclosure may comprise an antiferromagnetic layer, a non-magnetic conductive layer, a ferromagnetic layer, and a first electrode.

A non-magnetic conductive layer may be disposed on the antiferromagnetic layer.

A ferromagnetic layer may be disposed on the non-magnetic conductive layer.

A first electrode may be disposed on the antiferromagnetic layer. A first electrode may be in contact with one face of the non-magnetic conductive layer. An in-plane current may be introduced into the non-magnetic conductive layer via the first electrode. An input-spin current generated by the in-plane current may be provided to the antiferromagnetic layer.

A first unit vector is defined to be parallel to at least one of an easy magnetization axis of an antiferromagnetic layer and a hard magnetization axis of the antiferromagnetic layer. A second unit vector is defined to be configured with component vectors of the first unit vector that are perpendicular to the input-spin current. A third unit vector is defined to be parallel to a polarization direction of the input-spin current. A dot product of the second unit vector and the third unit vector may be a first value. An absolute value of the first value may be greater than 0 and smaller than or equal to 1.

The ferromagnetic layer may be a thin film comprising a material of which an easy magnetization axis is perpendicular to a direction of the in-plane current and a polarization direction of the input-spin current.

The input-spin current may cause a precessional motion of a magnetization of a sub-lattice of the antiferromagnetic layer. The precessional motion of a magnetization may cause spin pumping in the antiferromagnetic layer. An output-spin current caused by the spin pumping may pass through the non-magnetic conductive layer to be provided to the ferromagnetic layer.

The output-spin current may comprise a spin current component polarized in a direction perpendicular to a direction of in-plane current and a polarization direction of input-spin current.

A magnetic memory device according to one embodiment of the present disclosure may further comprise an insulator layer and a fixed magnetic layer. The ferromagnetic layer may be a free magnetic layer of a magnetic tunnel junction (MTJ).

In one embodiment of the present disclosure, each of the free magnetic layer and the fixed magnetic layer may comprise at least one of Fe, Co, Ni, B, Si, and Zr.

In one embodiment of the present disclosure, the non-magnetic conductive layer may comprise at least one of Cu, Ta, Pt, W, Ti, and Bi.

In one embodiment of the present disclosure, the antiferromagnetic layer may comprise at least one of Ru, Ir, Pt, Mn, Cr, FeMn, NiO, and Fe₂O₃ or an oxide thereof.

According to one embodiment of the present disclosure, by using a spin current caused by spin pumping, it is possible to provide a magnetic memory device that is not only capable of field-free switching the magnetization direction of a free magnetic layer without applying an external magnetic field but also with a significantly decreased switching current density.

According to one embodiment of the present disclosure, it is possible to provide a magnetic memory device with a spin current caused by spin pumping capable of switching the magnetization direction of a free magnetic layer by selecting at least one of a relationship between the polarization direction of a spin current provided to an antiferromagnetic layer and the direction of an easy magnetization axis of the antiferromagnetic layer and a relationship between the polarization direction of the spin current provided to the antiferromagnetic layer and the direction of a hard magnetization axis of the antiferromagnetic layer.

### BRIEF DESCRIPTION OF THE DRAWINGS

FIG. 1 illustrates an exemplary magnetic memory device according to one embodiment of the present disclosure.

FIG. 2a illustrates an azimuthal angle of an easy magnetization axis or a hard magnetization axis of an antiferromagnetic layer.

FIG. 2b illustrates a polar angle of the easy magnetization axis or the hard magnetization axis of the antiferromagnetic layer.

FIGS. 3a to 3c illustrate an average value <θ_{FM,x}>, <θ_{FM,y}>, <θ_{FM,z}> of a spin current generation efficiency according to an azimuthal angle ϕₖ and a polar angle θₖ of the easy magnetization axis of the antiferromagnetic layer.

FIGS. 4a to 4c are graphs illustrating the characteristics of the magnetic memory device according to a magnetic anisotropy energy density k of the antiferromagnetic layer.

### DETAILED DESCRIPTION

Hereinafter, certain preferred embodiments of the present disclosure will be described with reference to the accompanied drawings. In the drawings, the proportions and dimensions of the illustrated elements may be exaggerated for effective description of the technical details.

Throughout the description, it shall be appreciated that terms such as “comprise,” “comprising,” “include” and “including” are intended to specify that there are certain features, numbers, steps, actions, elements, components, or any combination thereof described in the specification and not to exclude the possibility of presence or addition of one or more of other features, numbers, steps, actions, elements, components or any combination thereof.

Moreover, when a certain element is described to be “on” another element, it shall be appreciated that the particular element is above or below the other element and not necessarily located on an upper side of the other element in the gravitational direction.

Moreover, when an element is described to be “connected” or “coupled” to another element, it shall be appreciated that the particular element may not only be directly connected or coupled to the other element but also be indirectly connected or coupled to the other element by way of yet another element.

Moreover, while terms such as “first,” “second,” etc. may be used in describing an element, it shall be appreciated that these terms are used merely for distinguishing one element from other elements and not for defining the nature, order or sequence of the element.

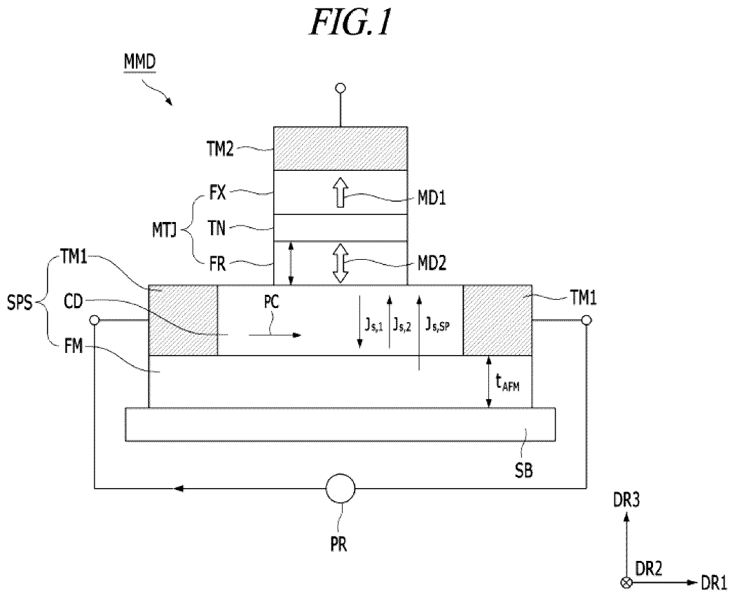

FIG. 1 illustrates an exemplary magnetic memory device MMD according to one embodiment of the present disclosure.

Referring to FIG. 1, a magnetic memory device MMD may include a substrate SB, a non-magnetic conductive layer CD, an antiferromagnetic layer AFM, a free magnetic layer FR, an insulator layer TN, and a fixed magnetic layer FX.

In one embodiment of the present disclosure, the substrate SB may be omitted.

When electricity is provided to the non-magnetic conductive layer CD, an in-plane current PC may flow parallel to a first direction DR1 in the non-magnetic conductive layer CD. In the present specification, being in-plane refers to being inside the non-magnetic conductive layer CD or being parallel to a lengthwise direction DR1 of the non-magnetic conductive layer CD. The non-magnetic conductive layer CD may be configured to receive electricity to generate a first spin current J_{s.1} and a second spin current J_{s.2}.

Specifically, the in-plane current PC may flow parallel to the first direction DR1 in the non-magnetic conductive layer CD. Here, the first spin current J_{s.1} and the second spin current J_{s.2} may be generated by the spin Hall effect. Each polarization direction of the first spin current J_{s.1} and the second spin current J_{s.2} may be parallel to a second direction DR2, which is perpendicular to the first direction DR1 and a third direction DR3. The third direction DR3 may be perpendicular to at least one of an interface of a non-magnetic conductive layer CD and a free magnetic layer FR and an interface of the non-magnetic conductive layer CD and the antiferromagnetic layer AFM.

The first spin current J_{s.1} may be transferred to the antiferromagnetic layer AFM. The second spin current J_{s.2} may be transferred to the free magnetic layer FR. The second spin current J_{s.2} may contribute to lowering a switching current density of the free magnetic layer FR.

The antiferromagnetic layer AFM may be in contact with one face of the non-magnetic conductive layer CD. The antiferromagnetic layer AFM may be configured to receive the first spin current J_{s.1} to generate a third spin current J_{s.SP}. The third spin current J_{s.SP} may be generated by spin pumping. The third spin current J_{s.SP} may switch a magnetism direction MD2 of a free magnetic layer.

Hereinafter, generating the third spin current J_{s.SP} in the antiferromagnetic layer AFM is described in detail. Upon providing the in-plane current PC to the non-magnetic conductive layer CD in a direction parallel to the first direction DR1, a spin polarized in a direction parallel to the second direction DR2 may move in a direction parallel to the third direction DR3 to generate the first spin current J_{s.1}. Accordingly, the spin polarized in a direction parallel to the second direction DR2 is accumulated in an interface of the non-magnetic conductive layer CD and the antiferromagnetic layer AFM, thereby generating a spin-orbit torque. Subsequently, the magnetization of the antiferromagnetic layer AFM may make a precessional motion by the spin-orbit torque. When the magnetization of a magnetic system makes a precessional motion, the spin current may spread to an adjacent interface. Such a phenomenon is referred to as spin pumping. That is, the third spin current J_{s.SP} may be generated when the magnetization of the antiferromagnetic layer AFM makes a precessional motion.

One face of the free magnetic layer FR may be in contact with the other face of the non-magnetic conductive layer CD. The free magnetic layer FR may be configured to receive the second spin current J_{s.2} and the third spin current J_{s.SP}. The magnetization direction of the free magnetic layer MD2 may be switched by the second spin current J_{s.2} and the third spin current J_{s.SP} The free magnetic layer FR may include a material of which the direction of an easy magnetization axis is parallel to the third direction DR3.

One face of the insulator layer TN may be in contact with the other face of the free magnetic layer FR. For example, the insulator layer TN may include at least one of AIOₓ, MgO, TaOₓ and ZrOₓ. In one embodiment of the present disclosure, the insulator layer TN may be omitted.

One face of the fixed magnetic layer FX may be in contact with the other face of the insulator layer TN. A magnetization direction MD1 of the fixed magnetic layer may be stably maintained. The fixed magnetic layer FX may include a material of which the direction of an easy magnetization axis is parallel to the third direction DR3. In one embodiment of the present disclosure, the fixed magnetic layer FX may be omitted.

The resistance of a magnetic tunnel junction MTJ may vary according to the magnetization direction of the free magnetic layer FR and the magnetization direction of the fixed magnetic layer FX. Based on these characteristics, the magnetic memory device MMD may be used for writing 0 or 1.

In order for the third spin current J_{s.SP} generated in the antiferromagnetic layer AFM to switch the magnetism direction MD2 of the free magnetic layer, it is required that the third spin current J_{x.SP} has a spin current component polarized in a direction parallel to the third direction DR3. Hereinafter, conditions for the third spin current J_{x.SP} to have spin current components polarized in a direction parallel to the third direction DR3 are described in detail.

A motion equation for magnetization of a sub-lattice of an antiferromagnetic system including a spin-orbit torque may be expressed as shown in Equation 1 below.

$$\frac{\partial {m}_{i}}{\partial t} = - {γ}_{i} {m}_{i} \times {H}_{eff , i} + α {m}_{i} \times \frac{\partial {m}_{i}}{\partial t} + {γ}_{i} \frac{\text{?} θ \text{?} J}{2 \text{?} M \text{?}} {m}_{i} \times ( {m}_{i} \times \hat{y} ) \qquad Equation 1$$

$$\text{?} \text{indicates text missing or illegible when filed}$$

In Equation 1, mᵢ stands for a magnetization vector of an i-th sub-lattice of the antiferromagnetic layer AFM, Yᵢ stands for a gyromagnetic ratio of the i-th sub-lattice, M_{z,i} stands for a saturation magnetization value of the i-th sub-lattice of the antiferromagnetic layer AFM, H_{xsf.1} stands for an effective magnetic field vector of the i-th sub-lattice of the antiferromagnetic layer AFM, a stands for a Gilbert Damping constant, and τ_{AFM} stands for a thickness of the antiferromagnetic layer AFM. The effective magnetic field vector H_{ufrs} of the i-th sub-lattice of the antiferromagnetic layer AFM may be expressed as shown in Equation 2 below.

$${H}_{eff , i} = - \frac{2 A \text{?}}{M \text{?} {d}^{2}} {m}_{j} + \frac{2 K}{M \text{?}} ( {m}_{i} \cdot σ ) σ \qquad Equation 2$$

$$\text{?} \text{indicates text missing or illegible when filed}$$

In Equation 2, Aₛₓ stands for an antiferromagnetic exchange stiffness constant, stands for a lattice constant, which is a distance between sub-lattices of the antiferromagnetic layer AFM, mᵢ stands for a magnetization vector of another sub-lattice near mᵢ, k stands for a magnetic anisotropy energy density of the antiferromagnetic layer AFM, and σ stands a vector indicating a direction MD3 of either an easy magnetization axis or a hard magnetization axis of the antiferromagnetic layer AFM by magnetic anisotropy energy. When the magnetic anisotropy energy density K is greater than 0, σ stands for a vector indicating the direction MD3 of the easy magnetization axis of the antiferromagnetic layer AFM. Meanwhile, when the magnetic anisotropy energy density K is smaller than 0, σ stands for a vector indicating the direction MD3 of the hard magnetization axis of the antiferromagnetic layer AFM. σ can be expressed as shown in Equation 3 below.

$$σ = ( cos {ϕ}_{K} sin {θ}_{K} , sin {ϕ}_{K} sin {θ}_{K} , cos {θ}_{K} ) \qquad Equation 3$$

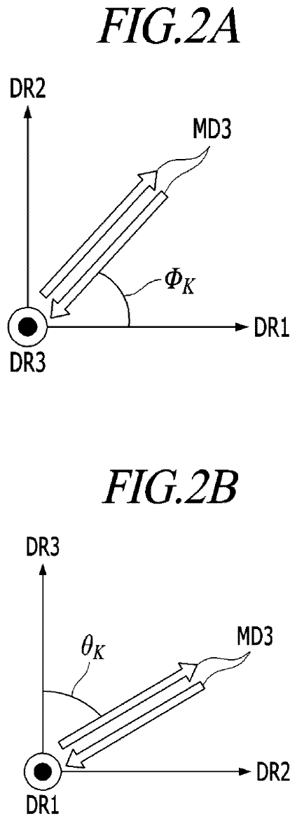

FIG. 2a is illustrated to describe azimuthal angles ϕₖ of the easy magnetization axis or the hard magnetization axis of the antiferromagnetic layer AFM. FIG. 2b is illustrated to describe polar angles θₖ of the easy magnetization axis or the hard magnetization axis of the antiferromagnetic layer AFM. In Equation 3, ϕₖ is an azimuthal angle of the easy magnetization axis or the hard magnetization axis of the antiferromagnetic layer AFM, and θₖ is a polar angle of the easy magnetization axis or the hard magnetization axis. That is, the azimuthal angle ϕₖ of the easy magnetization axis or the hard magnetization axis refers to an angle between the direction MD3 of the magnetization axis or the hard magnetization axis of the antiferromagnetic layer and the direction DR1 of x-axis. The polar angle θₖ of the easy magnetization axis or the hard magnetization axis refers to an angle between the direction MD3 of the easy magnetization axis or the hard magnetization axis of the antiferromagnetic layer and the direction DR3 of z-axis. Meanwhile, the third spin current J_{x.SP} may be expressed as shown in Equation 4 below.

$$J \text{?} = \frac{\text{?}}{8 π} g \text{?} ( {m}_{1} \times \frac{\partial {m}_{1}}{dt} + {m}_{2} \times \frac{\partial {m}_{2}}{\partial t} ) \qquad Equation 4$$

$$\text{?} \text{indicates text missing or illegible when filed}$$

In Equation 4, stands for a spin-mixing conductance, each of m₁ and m₂ stands for a magnetization vector of two sub-lattices forming the antiferromagnetic layer AFM, and J_{x.SP} stands for a third spin current. The relationship between electric current density J applied on the non-magnetic conductive layer CD and the third spin current J_{s.SP} is as shown in Equation 5 below. In the present disclosure, electric current refers to a current corresponding to the flow of electric charges, and spin current refers to a current corresponding to the flow of spin.

$$J \text{?} = \frac{\text{?} J}{2 \text{?}} ( θ \text{?} , θ \text{?} , θ ) \qquad Equation 5$$

$$\text{?} \text{indicates text missing or illegible when filed}$$

θ_{xp,x}, θ_{xp,y}, θ_{xp,z} stand, respectively, for spin current generation efficiencies of each polarization direction for the first direction DR1 (x-axis direction), the second direction DR2 (y-axis direction), and the third direction DR3 (z-axis direction). Specifically, the spin current generation efficiency refers to a ratio of generation of the third spin current J_{s.SP} by the electric current density J applied on the non-magnetic conductive layer CD. By using Equations 4 and 5,θ_{FM,x}, θ_{FM,y}, θ_{FM,z} may be expressed as shown in Equation 6 below.

$$θ \text{?} = {\frac{\text{?}}{4 π J} [ {m}_{1} \times \frac{\partial {m}_{1}}{\partial t} + {m}_{2} \times \frac{\partial {m}_{2}}{\partial t} ]}_{i} , i = x , y , z \qquad Equation 6$$

$$\text{?} \text{indicates text missing or illegible when filed}$$

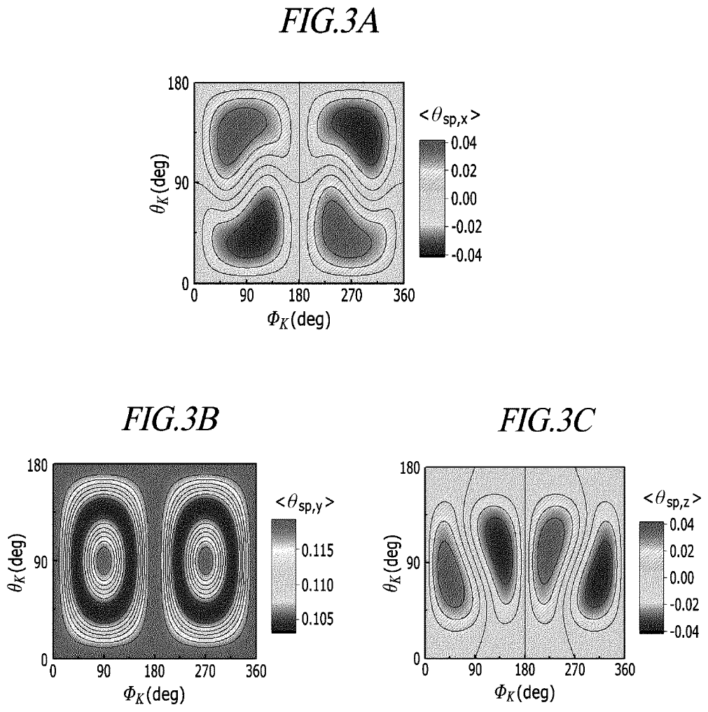

FIGS. 3a to 3c illustrate average values θ_{FM,x}, θ_{FM,y}, θ_{FM,z} of the spin current generation efficiencies according to the azimuthal angle ϕₖ and the polar angle θₖ of the easy magnetization axis of the antiferromagnetic layer. Specifically, FIGS. 3a to 3c are results of calculation of the average values θ_{FM,x}, θ_{FM,y}, θ_{FM,z} of the spin current generation efficiencies while making a precessional motion. The calculation results shown in FIGS. 3a to 3c are calculated by using a macrospin micromagnetic simulation based on a motion equation of magnetization.

The parameter values used for the macrospin micromagnetic simulation are as follows. Thickness of the antiferromagnetic layer AFM τ_{AFM}=3 nm, a lattice constant of the antiferromagnetic layer AFM d=0.4 nm saturation magnetization of the antiferromagnetic layer AFM M_{x.1}=M_{x.2}=1000 emn/cm³, Gilbert Damping constant of the antiferromagnetic layer AFM a=0.002, Gyromagnetic ratio of the antiferromagnetic layer AFM X: Y₁=Y₂=1.76×10⁷ Oe⁻¹s⁻¹, antiferromagnetic exchange interaction constant (antiferromagnetic exchange stiffness) Aₑᵣ=3×10⁻² erg/cm, effective magnetic anisotropy constant K=8×10⁸ erg/cm², spin Hall angle of the non-magnetic conductive layer CD θ_{SH}=0.2, spin-mixing conductance of the non-magnetic conductive layer CD [symbol] electric current density applied on the non-magnetic conductive layer CD I=10¹⁸ A/cm², pulse width (time of applying electric current density J on the non-magnetic conductive layer CD)=15 ns.

As described above, in order for the third spin current J_{s.SP} generated in the antiferromagnetic layer AFM to switch the magnetization direction MD2 of the free magnetic layer, the third spin current J_{s.SP} is required to have spin current components polarized in a direction parallel to the third direction DR3. Hereinafter, the conditions for the third spin current J_{s.SP} to have the spin current components polarized in a direction parallel to the third direction will be described with reference to FIG. 3c.

Referring to FIG. 3c, when the azimuthal angle ϕₖ of the easy magnetization axis of the antiferromagnetic layer AFM is one of 0 degree, 180 degrees and 360 degrees, the spin current generation efficiency θ_{op,z} of the third direction DR3 (z-axis direction) may be 0 regardless of the polar angle θₖ of the easy magnetization axis. That is, when the azimuthal angle ϕₖ of the easy magnetization axis of the antiferromagnetic AFM is one of 0 degree, 180 degrees and 360 degrees, the third spin current J_{x.SP} may not have a spin current component polarized in a direction parallel to the third direction DR3.

By contrast, when the azimuthal angle ϕₖ of the easy magnetization axis of the antiferromagnetic AFM is not at least one of 0 degree, 180 degrees and 360 degrees, the third spin current J_{s.SP} may have a spin current component polarized in a direction parallel to the third direction DR3. Such a relationship may be simply expressed as follows. “When \acute{σ}·ŷ≠0, the spin current generation efficiency θ_{op,x} for the third direction DR3 (z-axis direction) may have a value other than 0 depending on the polar angle θₖ of the easy axis of magnetization.” Here, ŷ is a polarization direction DR2 of the first spin current introduced by the spin Hall effect. σ is a unit vector indicating the direction MD3 of the easy magnetization axis of the antiferromagnetic layer by magnetic anisotropy energy. \acute{σ} is a unit vector configured with component vectors the unit vector σ that are perpendicular to the third direction DR3.

In conclusion, when the described condition \acute{σ}·ŷ≠0 is satisfied, the third spin current J_{x.SP} may have spin current components polarized in a direction parallel to the third direction DR3, and the magnetization direction MD2 of the free magnetic layer may be switched by the third spin current J_{x.SP}. Accordingly, the present disclosure allows field-free switching of the magnetization direction MD2 of the free magnetic layer without an external magnetic field.

In an embodiment of the present disclosure, a first unit vector (not shown) is defined to be parallel to at least one of the easy magnetization axis of the antiferromagnetic layer and the hard magnetization axis of the antiferromagnetic layer. That is, a first unit vector may be parallel to σ. A second unit vector \acute{σ} (not shown) is defined to be configured with component vectors of the first unit vector that are perpendicular to at least one of the first spin current direction, the second spin current direction, and the third spin current direction. A third unit vector ŷ (not shown) is defined to be parallel to the polarization direction DR2 of the first spin current. A dot product of the second unit vector \acute{σ} and the third unit vector ŷ may be a first value. An absolute value of the first value may be greater than 0 and smaller than or equal to 1. That is, when the absolute value of the first value is greater than 0 and smaller than or equal to 1, the third spin current J_{s.SP} may have spin current components polarized in a direction parallel to the third direction DR3, as described above. This may be the same as the condition \acute{σ}·ŷ≠0 described above. In one embodiment of the present disclosure, a fourth unit vector (not shown) is defined to be configured with component vectors of the first unit vector that are parallel to at least one of the first spin current direction, the second spin current direction, and third third spin current direction. A fifth unit vector (not shown) is defined to be parallel to at least one of the first spin current direction, the second spin current direction, and the third spin current direction. A dot product of the fourth unit vector and the fifth unit vector may be 0. That is, the polar angle θₖ of at least one of the easy magnetization axis and the hard magnetization axis of the antiferromagnetic layer AFM may be 90 degrees. For example, an absolute value of the first value may be greater than 0.00001 and smaller than or equal to 1. However, the absolute value of the first value of the present disclosure is not limited what is described herein.

In one embodiment of the present disclosure, the free magnetic layer FR of the magnetic memory device MMD may include at least one of Fe, Co, Ni, B, Si, and Zr. The fixed magnetic layer FX may include at least one of Fe, Co, Ni, B, Si, and Zr.

In one embodiment of the present disclosure, the magnetic memory device MMD may further include a first electrode TM1 and a power supply unit PR. The first electrode TM1 may be electrically connected to the non-magnetic conductive layer CD. The power supply unit PR may provide electricity to the non-magnetic conductive layer CD through the first electrode TM1. The first electrode TM1 may be provided in plurality.

In one embodiment of the present disclosure, the first electrode TM1 of the magnetic memory device MMD may include at least one of Cu, Ta, Pt, W, Ti, Bi and Ir.

In one embodiment of the present disclosure, the antiferromagnetic layer AFM of the magnetic memory device MMD may include at least one of Ru, Ir, Pt, Mn, Cr, FeMn, NiO, and Fe₂O₃. Alternatively, the antiferromagnetic layer AFM may include an oxide of at least one of Ru, Ir, Pt, Mn, Cr, FeMn, NiO, and Fe₂O₃.

In one embodiment of the present disclosure, the non-magnetic conductive layer CD of the magnetic memory device MMD may include at least one of Cu, Ta, Pt, W, Ti, and Bi.

In one embodiment of the present disclosure, the magnetic memory device MMD may further include a second electrode TM2. The second electrode TM2 may be electrically connected to the fixed magnetic layer FX.

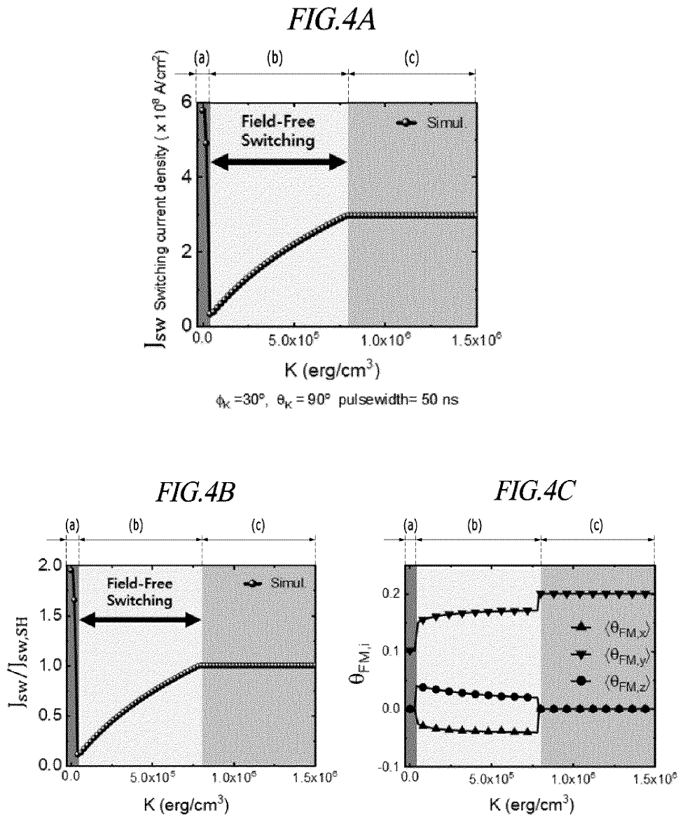

FIGS. 4a to 4c are graphs illustrating characteristics of the magnetic memory device MMD according to a magnetic anisotropy energy density. The magnetic anisotropy energy density is a physical quantity indicating the characteristics of magnetization of a material in a specific direction. Hereinafter, the graphs shown in FIGS. 4a to 4c will be described in detail.

Referring to FIG. 1, by the in-plane current PC injected into the non-magnetic conductive layer CD through the first electrode TM1, the first spin current J_{s.1} and the second spin current J_{s.2} are generated by the spin Hall effect. The first spin current J_{s.2} is provided to the non-ferromagnetic layer AFM, and the second spin current J_{s.2} is provided to the free magnetic layer FR. The first spin current J_{s.1} causes a precessional motion of a magnetization of the sub-lattice of the antiferromagnetic layer AFM, thereby generating the third spin current J_{s.SP} by the precessional motion. That is, the free magnetic layer FR receives the second spin current J_{s.2} and the third spin current J_{s.SP}.

Since the first spin current J_{s.1} and the second spin current J_{s.2} are spin currents by the spin Hall effect, they only have spin current components polarized in a direction parallel to the second direction DR2. Polarization components of the first spin current J_{s.1} and the second spin current J_{s.2} expressed in vector forms are as follows.

$$J \text{?} = \frac{\text{?} J}{2 e} ( 0 , {θ}_{SH} , 0 ) , J \text{?} = \frac{\text{?} J}{2 e} ( 0 , {θ}_{SH , F M} , 0 ) .$$

$$\text{?} \text{indicates text missing or illegible when filed}$$

Here, θ_{SH} is a spin Hall angle of the first spin current J_{s.1} provided to the antiferromagnetic layer AFM, and θ_{SH,FM} is a spin Hall angle of the second spin current J_{s.2} provided to the free magnetic layer FR. θ_{SH} and θ_{SH,FM} always have signs opposite to each other. The sum of the polar components of the second spin current J_{s.2} and the third spin current J_{s.SP} transferred to the free magnetic layer FR may be expressed as shown in Equation 7 below.

$$J \text{?} + J \text{?} = \frac{\text{?} J}{2 e} ( θ \text{?} , θ \text{?} + θ \text{?} , θ \text{?} ) \qquad Equation 7$$

$$\text{?} \text{indicates text missing or illegible when filed}$$

A motion equation of magnetization of the free magnetic layer FR having the second spin current J_{s.2} and the third spin current J_{x.SP} may be expressed as shown in Equation 8 below.

$$\frac{\partial \text{?}}{\text{?}} = - {γ}_{F M} {m}_{F M} \times {H}_{K , F M} + {α}_{F M} {m}_{F M} \times \frac{\partial \text{?}}{\text{?}} + θ \text{?} γ \text{?} {c}_{j} {m}_{F M} \times ( {m}_{F M} \times \hat{y} ) + θ \text{?} {γ}_{F M} {c}_{j} {m}_{F M} \times ( {m}_{F M} \times \hat{x} ) + θ \text{?} {γ}_{F M} {c}_{j} {m}_{F M} \times ( {m}_{F M} \times \hat{y} ) + θ \text{?} {γ}_{F M} {c}_{j} {m}_{F M} \times ( {m}_{F M} \times z ) , \qquad Equation 8$$

$${c}_{j} = \frac{\text{?} J}{2 \text{?} M \text{?} {τ}_{F M}}$$

$$\text{?} \text{indicates text missing or illegible when filed}$$

Here, m_{FM} represents a magnetization vector of the free magnetic layer FR, Y_{FM} represents a gyromagnetic ratio of the free magnetic layer FR, M_{s.FM} represents a saturation magnetization value of the free magnetic layer FR, H_{K,FM} represents an effective magnetic field of perpendicular magnetic anisotropy energy applied on the free magnetic layer FR, a_{FM} represents a Gilbert damping constant of the free magnetic layer FR, θ_{SH.FM} represents a spin Hall angle of the second spin current J_{s.2} provided to the free magnetic layer FR, and τ_{FM} represents the thickness of the free magnetic layer FR.

The first spin current J_{s.1} only has polarization components in a direction parallel to the second direction DR2 (y-axis direction). This may be shown in a vector form as

$${J}_{s , 1} = \frac{\text{?} J}{2 e} ( 0 , {θ}_{SH} , 0 ) .$$

$$\text{?} \text{indicates text missing or illegible when filed}$$

Here, h is a value of a Plank constant divided by 2π, which is =1.05×10⁻³⁴ J sec, θ is an electric charge quantity of an electron, which is =1.6×10⁻¹⁹ C, J is a charge current density applied to the non-magnetic conductive layer CD, θ_{SH} is a spin Hall angle, which is obtained by dividing the first spin current J_{s.1} generated by the spin Hall effect of the non-magnetic conductive layer CD with a charge current J applied to the non-magnetic conductive layer.

Parameters of structures and physical properties related to the magnetic memory device MMD corresponding to FIGS. 4a to 4c are as follows.

Thickness of the antiferromagnetic layer AFM τ_{AFM}=3 nm, a lattice constant of the =3 nm antiferromagnetic layer AFM d=0.4 nm, saturation magnetization of the antiferromagnetic layer AFM M_{x.1}=M_{x.2}=1000 emo/cm²-Gilbert damping constant of the antiferromagnetic layer a=0.003, a gyromagnetic ratio of the antiferromagnetic layer AFM Y₁=Y₂=1.76×10⁷ Oe⁻¹s⁻¹, an antiferromagnetic exchange interaction constant (antiferromagnetic exchange stiffness) A_{o,x}=10×10⁻⁷ erg/cm, an effective magnetic anisotropy constant K 0≤K≤1.5×10⁶ erg/cm³, an azimuthal angle of the easy magnetization axis of the antiferromagnetic layer AFM ϕₖ=30°, a polar angle of the easy magnetization axis of the antiferromagnetic layer AFM θₖ=90°, a spin Hall angle of the second spin current J_{s.2} provided to the free magnetic layer FR θ_{SH,FM}=0.2, spin-mixing conductance of the non-magnetic conductive layer CD gᵣ^{F1}=6×10¹⁴ cm⁻², time of applying electric current density J on the non-magnetic conductive layer CD (pulse width)=50 ns, thickness of the free magnetic layer FR τ_{FM}=1 mm, saturation magnetization of the free magnetic layer FR M_{s,FM}=1000 emu/cm³, a Gilbert damping constant of the free magnetic layer FR a_{FM}=0.01, a gyromagnetic ratio of the free magnetic layer FR Y_{FM}=1.76×10⁷ Oe⁻¹s⁻¹, a size of effective magnetic field of perpendicular magnetic anisotropy applied on the free magnetic layer FR H_{KFNE}=4000 Oe.

In each of FIGS. 4a to 4c, the region marked with (a) may be a region where magnetization of the antiferromagnetic layer AFM goes through a precessional motion based on a rotational axis parallel to the second direction DR2 (y-axis direction).

In each of FIGS. 4a to 4c, the region marked with (b) may be a region where magnetization of the antiferromagnetic layer AFM goes through a precessional motion based on a rotational axis parallel to the third direction DR3 (z-axis direction).

In each of FIGS. 4a to 4c, the region marked with (c) may be a region where magnetization of the antiferromagnetic layer AFM does not go through a precessional motion due to a relatively higher magnetic anisotropy density K of the antiferromagnetic layer AFM than the charge current density J applied to the non-magnetic conductive layer CD.

FIG. 4a is a graph illustrating a first switch current density J_{sw} of the free magnetic layer according to the magnetic anisotropy density K of the antiferromagnetic layer AFM. The first switching current density J_{SW} of the free magnetic layer is calculated taking account of both the second spin current J_{s.2} by the spin Hall effect and the third spin current J_{aSP} by the spin pumping. The first switching current density J_{SW} refers to a current density required for switching the magnetization direction MD2 of the free magnetic layer.

In the region marked with (b) in FIG. 4a, the lower the magnetic anisotropy density K of the antiferromagnetic layer AFM, the more the first switching current density J_{SW} of the free magnetic layer decreases. In the region (b) of FIG. 4a, the rotational axis of a precessional motion of magnetization of the antiferromagnetic layer AFM has directional components parallel to the third direction DR3 (z-axis direction). Accordingly, the third spin current J_{aSP} by spin pumping also has a spin current component polarized in a direction parallel to the third direction DR3. This can be also confirmed by the fact that the average value (θ_{FM,x}) of the spin current generation efficiencies for the third direction DR3 is not 0, in the region marked with (b) in FIG. 4c.

In the region marked with (c) in FIG. 4a, the third spin current J_{s.SP} is not generated because the magnetization of the antiferromagnetic layer AFM does not make a precessional motion. Accordingly, in the region marked with (c) in FIG. 4a, it can be seen that the first switching current density J_{SW} is constantly maintained for the magnetic anisotropy density K of the antiferromagnetic layer AFM.

FIG. 4b illustrates that the first switching current density of the free magnetic layer is decreased by the third spin current J_{s.SP}.

Referring to FIG. 4b, the first switching current density J_{SW} of the free magnetic layer is calculated taking account of both the second spin current J_{s.2} by the spin Hall effect and the third spin current J_{s.SP} by the spin pumping. On the contrary, the second switching current density J_{SWSH} of the free magnetic layer is calculated taking account of the second spin current J_{s.2} by the spin Hall effect only. That is, the smaller the ratio of the first switching current density J_{SW} to the second switching current density J_{SWSH} is than 1, the greater the effect of decrease of the switching current density of the free magnetic layer by the third spin current J_{s.SP} is.

FIG. 4c illustrates average values of the spin current generation efficiencies ((θ_{FM,x}), (θ_{FM,y}), (θ_{FM,z})) for the first direction DR1 (x-axis direction), the second direction DR2 (y-axis direction), and the third direction DR3 (z-axis direction), respectively. In the region marked with (c) in FIG. 4c, the average value of the spin current generation efficiencies applied to the free magnetic layer FR may be calculated as follows: (θ_{FM,x})=0, (θ_{FM,y})=0.2, (θ_{FM,z})=0. In addition, it is (θ_{FM,y}) is calculated to have the same value as θ_{SH,FM}.

In conclusion, when the magnetic anisotropy density of the antiferromagnetic layer AFM is K=4×10⁴ erg/cm³, the maximum value of (θ_{FM,z}) is calculated to be 0.04 (see FIG. 4c), and the first switching current density J_{SW} of the free magnetic layer is calculated to be 0.32×10⁸ A/cm² (see FIG. 4a). That is, the first switching current density J_{SW} is equal to the value of the second switching current density reduced by about 89%. This means that the switching current density of the free magnetic layer is reduced by about 89% by the third spin current J_{s.SW} generated in the spin pumping structure SPS. Therefore, by using the present disclosure, it is possible to realize a magnetic memory device with significantly reduced switching current density in the free magnetic layer.

In one embodiment of the present disclosure, the magnetic memory device MMD may include a spin pumping structure SPS and a magnetic tunnel junction MTJ.

The spin pumping structure SPS may include the antiferromagnetic layer AFM and the non-magnetic conductive layer CD.

The magnetic tunnel junction may be disposed on the spin pumping structure SPS. The magnetic tunnel junction may include the free magnetic layer FR, the insulator layer TN, and the fixed magnetic layer FX.

The non-magnetic conductive layer CD may be configured to receive electric power to generate the first spin current J_{s.1} and the second spin current J_{s.2} by the spin Hall effect. The antiferromagnetic layer AFM may be configured to receive the first spin current J_{s.1} to generate the third spin current J_{s.SW} by the spin pumping. The free magnetic layer FR may be configured to receive the second spin current J_{s.2} and the third spin current J_{s.SW}. The magnetization direction MD2 of the free magnetic layer may be switched by the second spin current J_{s.2} and the third spin current J_{x.SP}.

In one embodiment of the present disclosure, the first unit vector (not shown) is defined to be parallel to at least one of the easy magnetization axis of the antiferromagnetic layer and the hard magnetization axis of the antiferromagnetic layer. That is, the first unit vector may be parallel to σ. The second unit vector \acute{σ} (not shown) is defined to be configured with component vectors of the first unit vector that are perpendicular to at least one of the first spin current direction, the second spin current direction, and the third spin current direction. The third unit vector ŷ (not shown) is defined to be parallel to the polarization direction DR2 of the first spin current. The dot product of the second unit vector \acute{σ} and the third unit vector ŷ may be the first value. The absolute value of the first value may be greater than 0 and smaller than or equal to 1. That is, when the absolute value of the first value is greater than 0 and smaller than or equal to 1, the third spin current J_{s.SP} may have spin current components polarized in a direction parallel to the third direction DR3, as described above. This may have the same meaning as the condition \acute{σ}·ŷ≠0 described above. In one embodiment of the present disclosure, the fourth unit vector (not shown) is defined to be configured with component vectors of the first unit vector that are parallel to at least one of the first spin current direction, the second spin current direction, and the third spin current direction. The fifth unit vector (not shown) is defined to be parallel to at least one of the first spin current direction, the second spin current direction, and the third spin current direction. The dot product of the fourth unit vector and the fifth unit vector may be 0. That is, the polar angle θ_{K} of at least one of the easy magnetization axis and the hard magnetization axis of the antiferromagnetic layer AFM may be 90 degrees. For example, the absolute value of the first value may be greater than 0.00001 and smaller than or equal to 1. However, the absolute value of the first value of the present disclosure is not limited to what is described herein.

In one embodiment of the present disclosure, the magnetic memory device MMD may further include the first electrode TM1 and the power supply unit PR. The first electrode TM1 may be electrically connected to the non-magnetic conductive layer CD. The power supply unit PR may supply electric power to the non-magnetic conductive layer CD via the first electrode TM1. The first electrode TM1 may be provided in plurality.

In one embodiment of the present disclosure, the magnetic memory device MMD may include at least one of Cu, Ta, Pt, W, Ti, Bi, and Ir.

In one embodiment of the present disclosure, the free magnetic layer FR of the magnetic memory device MMD may include at least one of Fe, Co, Ni, B, Si, and Zr. The fixed magnetic layer FX may include at least one of Fe, Co, Ni, B, Si, and Zr.

In one embodiment of the present disclosure, the antiferromagnetic layer AFM of the magnetic memory device MMD may include at least one of Ru, Ir, Pt, Mn, Cr, FeMn, NiO, and Fe₂O₃. Alternatively, the antiferromagnetic layer AFM may include an oxide of at least one of Ru, Ir, Pt, Mn, Cr, FeMn, NiO, and Fe₂O₃.

In one embodiment of the present disclosure, the non-magnetic conductive layer CD of the magnetic memory device MMD may include at least one of Cu, Ta, Pt, W, Ti, and Bi.

In one embodiment of the present disclosure, the magnetic memory device MMD may further include the second electrode TM2. The second electrode TM2 may be electrically connected to the fixed magnetic layer FX.

The magnetic memory device MMD according to one embodiment of the present disclosure may include the antiferromagnetic layer AFM, the non-magnetic conductive layer CD, the ferromagnetic layer (not shown), and the first electrode TM1.

In the present specification, an input-spin current may refer to the first spin current J_{s.1}. In addition, an output-spin current may refer to the third spin current J_{s.SP}.

The antiferromagnetic layer AFM may be disposed on the substrate SB. The first unit vector (not shown) is defined to be parallel to at least one of the easy magnetization axis of the antiferromagnetic layer AFM and the hard magnetization axis of the antiferromagnetic layer AFM. That is, the first vector may be parallel to σ. The second unit vector \acute{σ} (not shown) is defined to be configured with component vectors of the first unit vector that are perpendicular to the input-spin current. The third unit vector ŷ (not shown) is defined to be parallel to the polarization direction DR2 of the input-spin current. The dot product of the second unit vector \acute{σ} and the third unit vector ŷ may be the first value. The absolute value of the first value may be greater than 0 and smaller than or equal to 1. That is, when the absolute value of the first value is greater than 0 and smaller than or equal to 1, the output-spin current J_{s.SP} may have spin current components polarized in a direction parallel to the third direction DR3, as described above. This may have the same meaning as the condition \acute{σ}·ŷ≠0 described above.

The non-magnetic conductive layer CD may be disposed on the antiferromagnetic layer AFM.

The ferromagnetic layer may be disposed on the non-conductive layer CD. The ferromagnetic layer may be a thin film including a material of which the direction MD3 of the easy magnetization axis is perpendicular to the direction MD1 of the in-plane current and the polarization direction DR2 of the input-spin current.

The first electrode TM1 may be disposed on the antiferromagnetic layer AFM. The first electrode TM1 may be in contact with one face of the non-magnetic conductive layer CD. The in-plane current PC may be introduced to the non-magnetic conductive layer CD via the first electrode TM1. In one embodiment of the present disclosure, the first electrode TM1 may be provided in plurality.

The input-spin current generated by the in-plane current PC may be provided to the antiferromagnetic layer AFM. The input-spin current may cause a magnetization precessional motion of the sub-lattice of the antiferromagnetic layer AFM. The magnetization precessional motion of the sub-lattice of the antiferromagnetic layer AFM may cause the spin pumping in the antiferromagnetic layer AFM. The output-spin current by the spin pumping may be provided to the ferromagnetic layer via the non-magnetic conductive layer CD.

The output-spin current may include a spin current component polarized in the direction DR3 perpendicular to the direction DR1 of the in-plane current and the polarization direction DR2 of the input-spin current.

The magnetic memory device MMD according to one embodiment of the present disclosure may further include the insulator layer TN and the fixed magnetic layer FX. In addition, the ferromagnetic layer may be the free magnetic layer FR of the magnetic tunnel junction MTJ.

The free magnetic layer FR and the fixed magnetic layer FX of the magnetic memory device MMD according to one embodiment of the present disclosure may each include at least one of Fe, Co, Ni, B, Si, and Zr.

The non-magnetic conductive layer CD of the magnetic memory device MMD according to one embodiment of the present disclosure may include at least one of Cu, Ta, Pt, W, Ti, and Bi.

The antiferromagnetic layer AFM of the magnetic memory device MMD according to one embodiment of the present disclosure may include at least one of Ru, Ir, Pt, Mn, Cr, FeMn, NiO, and Fe₂O₃. Alternatively, the antiferromagnetic layer AFM may include an oxide of at least one of Ru, Ir, Pt, Mn, Cr, FeMn, NiO, and Fe₂O₃.

In one embodiment of the present disclosure, the first electrode TM1 of the magnetic memory device MMD may include at least one of Cu, Ta, Pt, W, Ti, Bi, and Ir.

While certain embodiments of the present disclosure have been described above, anyone ordinarily skilled in the art to which the present disclosure pertains shall appreciate that there may be a variety of modifications and permutations of the present disclosure without departing from the technical ideas and scopes of the present disclosure that are defined in the appended claims. Moreover, it shall be appreciated that the disclosed embodiments are not intended to restrict the present disclosure thereto and that every technical idea within the appended claims and their equivalents is interpreted to be included in the scope of the present disclosure.

What is claimed is:

1. A magnetic memory device, comprising:
a non-magnetic conductive layer configured to receive electric power to generate a first spin current and a second spin current by the spin Hall effect;
an antiferromagnetic layer being in contact with one face of the non-magnetic conductive layer and configured to receive the first spin current to generate a third spin current by spin pumping; and
a free magnetic layer with one face thereof being in contact with the other face of the non-magnetic conductive layer and configured to receive the second spin current and the third spin current,
wherein a magnetization direction of the free magnetic layer is switched by the second spin current and the third spin current.

2. The magnetic memory device of claim 1,
wherein a first unit vector is defined to be parallel to at least one of an easy magnetization axis of the antiferromagnetic layer and a hard magnetization axis of the antiferromagnetic layer,
wherein a second unit vector is defined to be configured with component vectors of the first unit vector that are perpendicular to at least one of a direction of the first spin current, a direction of the second spin current, and a direction of the third spin current,
wherein a third unit vector is defined to be parallel to a polarization direction of the first spin current, and
wherein a dot product of the second unit vector and the third unit vector is a first value, and an absolute value of the first value is greater than 0 and smaller than or equal to 1.

3. The magnetic memory device of claim 2, further comprising:
an insulator layer with one face thereof being in contact with the other face of the free magnetic layer; and
a fixed magnetic layer with one face thereof being in contact with the other face of the insulator layer.

4. The magnetic memory device of claim 3,
wherein each of the free magnetic layer and the fixed magnetic layer comprises at least one of Fe, Co, Ni, B, Si, and Zr.

5. The magnetic memory device of claim 3, further comprising:
a first electrode electrically connected to the non-magnetic conductive layer; and
a power supply unit configured for providing electric power to the non-magnetic conductive layer via the first electrode.

6. The magnetic memory device of claim 5,
wherein the first electrode comprises at least one of Cu, Ta, Pt, W, Ti, Bi, and Ir.

7. The magnetic memory device of claim 1,
wherein the antiferromagnetic layer comprises at least one of Ru, Ir, Pt, Mn, Cr, FeMn, NiO, and Fe₂O₃ or an oxide thereof.

8. The magnetic memory device of claim 1,
wherein the non-magnetic conductive layer comprises at least one of Cu, Ta, Pt, W, Ti, and Bi.

9. A magnetic memory device, comprising:
a spin pumping structure comprising an antiferromagnetic layer and a non-magnetic conductive layer; and
a magnetic tunnel junction structure disposed on the spin pumping structure and comprising a free magnetic layer, an insulator layer, and a fixed magnetic layer,
wherein the non-magnetic conductive layer is configured to receive electric power to generate a first spin current and a second spin current by the spin Hall effect,
wherein the antiferromagnetic layer is configured to receive the first spin current to generate a third spin current by spin pumping,
wherein the free magnetic layer is configured to receive the second spin current and the third spin current, and
wherein a magnetization direction of the free magnetic layer is switched by the second spin current and the third spin current.

10. The magnetic memory device of claim 9,
Wherein a first unit vector is defined to be parallel to at least one of an easy magnetization axis of the antiferromagnetic layer and a hard magnetization axis of the antiferromagnetic layer,
wherein a second unit vector is defined to be configured with component vectors of the first unit vector that are perpendicular to at least one of a direction of the first spin current, a direction of the second spin current, and a direction of the third spin current,
wherein a third unit vector is defined to be parallel to a polarization direction of the first spin current, and
wherein a dot product of the second unit vector and the third unit vector is a first value, and an absolute value of the first value is greater than 0 and smaller than or equal to 1.

11. The magnetic memory device of claim 10, further comprising:
a first electrode electrically connected to the non-magnetic conductive layer; and
a power supply unit configured for providing electric power to the non-magnetic conductive layer via the first electrode.

12. The magnetic memory device of claim 11,
wherein the first electrode comprises at least one of Cu, Ta, Pt, W, Ti, Bi, and Ir.

13. The magnetic memory device of claim 9,
wherein each the free magnetic layer and the fixed magnetic layer comprises at least one of Fe, Co, Ni, B, Si, and Zr.

14. The magnetic memory device of claim 9,
wherein the antiferromagnetic layer comprises at least one of Ru, Ir, Pt, Mn, Cr, FeMn, NiO, and Fe₂O₃ or at least one oxide thereof.

15. The magnetic memory device of claim 9,
wherein the non-magnetic conductive layer comprises at least one of Cu, Ta, Pt, W, Ti, and Bi.

16. A magnetic memory device, comprising:
an antiferromagnetic layer;
a non-magnetic conductive layer disposed on the antiferromagnetic layer;
a ferromagnetic layer disposed on the non-magnetic conductive layer; and
a first electrode disposed on the antiferromagnetic layer and being in contact with one face of the non-magnetic conductive layer,
wherein an in-plane current is introduced into the non-magnetic conductive layer via the first electrode, and an input-spin current generated by the in-plane current is provided to the antiferromagnetic layer,
wherein a first unit vector is defined to be parallel to at least one of an easy magnetization axis of the antiferromagnetic layer and a hard magnetization axis of the antiferromagnetic layer,
wherein a second unit vector is defined to be configured with component vectors of the first unit vector that are perpendicular to the input-spin current,
wherein a third unit vector is defined to be parallel to a polarization direction of the input-spin current,
wherein a dot product of the second unit vector and the third unit vector is a first value, and an absolute value of the first value is greater than 0 and smaller than or equal to 1,
wherein the ferromagnetic layer is a thin film comprising a material of which an easy magnetization axis direction is perpendicular to a direction of the in-plane current and a polarization direction of the input-spin current,
wherein the input-spin current causes a precessional motion of a magnetization of a sub-lattice of the antiferromagnetic layer, and the precessional motion of a magnetization causes spin pumping in the antiferromagnetic layer, and an output-spin current caused by the spin pumping passes through the non-magnetic conductive layer to be provided to the ferromagnetic layer, and
wherein the output-spin current comprises spin current components polarized in a direction perpendicular to a direction of the in-plane current and a polarization direction of the input-spin current.

17. The magnetic memory device of claim 16, further comprising an insulator layer and a fixed magnetic layer,
wherein the ferromagnetic layer is a free magnetic layer of a magnetic tunnel junction (MTJ).

18. The magnetic memory device of claim 17,
wherein each of the free magnetic layer and the fixed magnetic layer comprises at least one of Fe, Co, Ni, B, Si, and Zr.

19. The magnetic memory device of claim 17,
wherein the non-magnetic conductive device comprises at least one of Cu, Ta, Pt, W, Ti, and Bi.

20. The magnetic memory device of claim 17,
wherein the antiferromagnetic layer comprises at least one of Ru, Ir, Pt, Mn, Cr, FeMn, NiO, and Fe₂O₃ or at least one oxide thereof.
